(19) United States
(12) Patent Application Publication
(10) Pub. No.: US 2023/0030188 A1
(43) Pub. Date: Feb. 2, 2023

(54) ADSORBENTS AND METHODS FOR REDUCING CONTAMINATION IN WAFER CONTAINER MICROENVIRONMENTS

(71) Applicant: ENTEGRIS, INC., Billerica, MA (US)

(72) Inventors: Charles Miller, Taunton, MA (US); Alissa Wild, Chaska, MN (US)

(21) Appl. No.: 17/871,249

(22) Filed: Jul. 22, 2022

Related U.S. Application Data
(60) Provisional application No. 63/224,564, filed on Jul. 22, 2021.

(51) Int. Cl. H01L 21/673; G01N 30/93; G01N 30/95

(52) U.S. Cl. CPC H01L 21/67393; G01N 30/93; G01N 30/95

(57) ABSTRACT

Adsorbents can be structured for use in a wafer container microenvironment. The loading of these adsorbents can be tailored to the particular contaminants to be removed from the wafer container microenvironment. The loading can include adsorbents for one or more contaminants, the contaminants including acids, bases, condensable organic compounds, and/or volatile organic compounds. The adsorbent can further include a moisture removal material such as a molecular sieve. The contaminants to be removed can be determined by cleaning or staging conditions for the wafer container, testing of previous adsorbents used in processes.

### FIELD

This disclosure is directed to adsorbents configured for use in wafer containers, and methods of targeted removal of contaminants from wafer containers using such adsorbents.

### BACKGROUND

Processing of semiconductor wafers requires extremely clean conditions. However, the cleaning and/or staging of wafer containers, some process chemicals, and off-gassing from the wafer container itself can introduce contaminants to the microenvironment within the wafer container.

### SUMMARY

This disclosure is directed to adsorbents configured for use in wafer containers, and methods of targeted removal of contaminants from wafer containers using such adsorbents.

By incorporating an adsorbent into a wafer container, for example by providing an adsorbent that can fit in a wafer slot or a specialized accommodation within the wafer container, contaminants can be removed from the wafer container microenvironment. This can improve the cleanliness and purity of the wafer container microenvironment and thus improve the precision and yield of processes carried out within the wafer container microenvironment.

Potential contaminants within wafer containers can vary significantly from application to application based on differences in the process chemicals being used, cleaning and/or staging conditions, and the sensitivity of the particular process to different contaminants. By tailoring the loading of adsorbents based the particular application, the adsorbent loading can increase the effectiveness of removal for the contaminants of interest.

In an embodiment, a method of reducing contamination within a wafer container microenvironment includes determining one or more contaminants for removal from the wafer container microenvironment. The method further includes selecting one or more constituents for an adsorbent media based on the one or more contaminants. The method also includes determining a loading for each of the one or more constituents based on the one or more contaminants. The method further includes preparing an adsorbent material including the determined loading of each of the one or more constituents. The adsorbent material is configured to be placed within the wafer container microenvironment when wafers are present in the wafer container microenvironment.

In an embodiment, the one or more constituents for the adsorbent media are selected from the group consisting of carbon materials, molecular sieves, ion exchange resins, and zeolites.

In an embodiment, determining the one or more contaminants includes testing of a sample adsorbent that has been placed within a test wafer container microenvironment such that it has absorbed potential contaminants.

In an embodiment, determining the loading for each of the one or more constituents includes testing of a sample adsorbent that has been placed within a test wafer container microenvironment such that it has absorbed potential contaminants.

In an embodiment, determining the one or more contaminants is based on ambient conditions during staging of a wafer container defining the wafer container microenvironment.

In an embodiment, determining the loading for each of the one or more constituents is based on ambient conditions during staging of a wafer container defining the wafer container microenvironment.

In an embodiment, determining the one or more contaminants is based on a material composition of the wafer container defining the wafer container microenvironment.

In an embodiment, determining the loading for each of the one or more constituents is based on a material composition of the wafer container defining the wafer container microenvironment.

In an embodiment, determining the one or more constituents is based on one or more materials used in a process conducted within the wafer container microenvironment.

In an embodiment, determining the loading for each of the one or more constituents is based on one or more materials used in a process conducted within the wafer container microenvironment.

In an embodiment, a wafer container defining the wafer container microenvironment is a front opening unified pod (FOUP).

In an embodiment, the one or more contaminants selected from the group consisting of inorganic acids, bases, volatile organic compounds, and condensable organic compounds.

In an embodiment, the adsorbent material is shaped such that it can fit in a wafer slot of the wafer container microenvironment. In an embodiment, the adsorbent material has the same shape and dimensions as wafers configured to be placed within the wafer container microenvironment.

In an embodiment, the method further includes placing the adsorbent material within the wafer container microenvironment, and wherein the adsorbent material adsorbs the one or more contaminants when the contaminants are present within the microenvironment.

In an embodiment, the adsorbent material adsorbs the one or more contaminants during a wafer processing operation. In an embodiment, the adsorbent material adsorbs the one or more contaminants during a wafer storage operation.

In an embodiment, the adsorbent material is placed in an adsorbent holder located within the wafer container microenvironment.

### DRAWINGS

FIG. 1 shows an adsorbent for use in a wafer container according to an embodiment.

FIG. 2 shows a wafer container configured to accommodate an adsorbent according to an embodiment.

FIG. 3 shows a flowchart of a method for reducing specific contaminants within a wafer container according to an embodiment.

### DETAILED DESCRIPTION

This disclosure is directed to adsorbents configured for use in wafer containers, and methods of targeted removal of contaminants from wafer containers using such adsorbents.

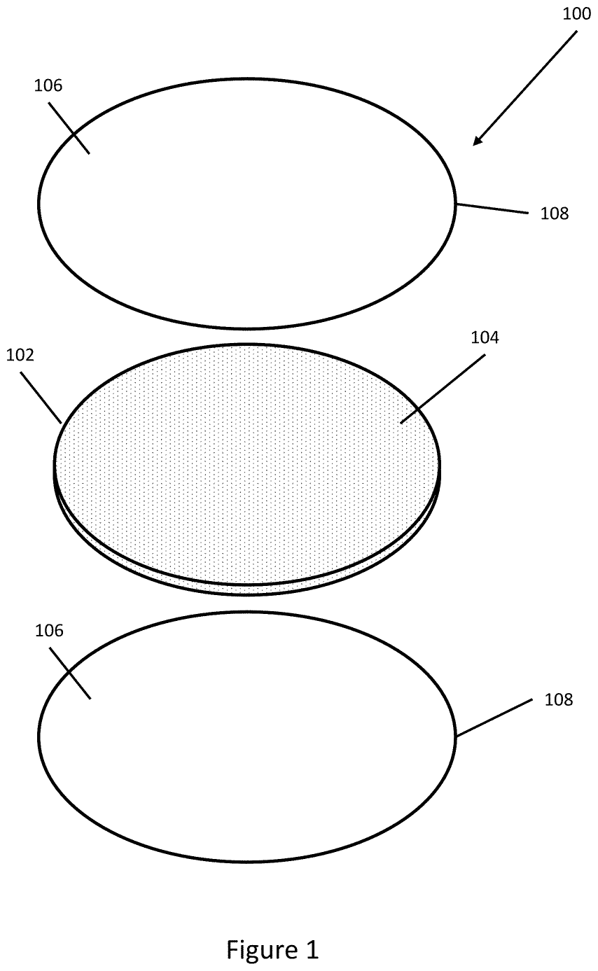

FIG. 1 shows an exploded view adsorbent for use in a wafer container according to an embodiment. Adsorbent 100 includes an adsorbent body 102 containing adsorbent media 104 and covering 106 surrounding the adsorbent media. The covering 106 can be sealed at perimeter 108

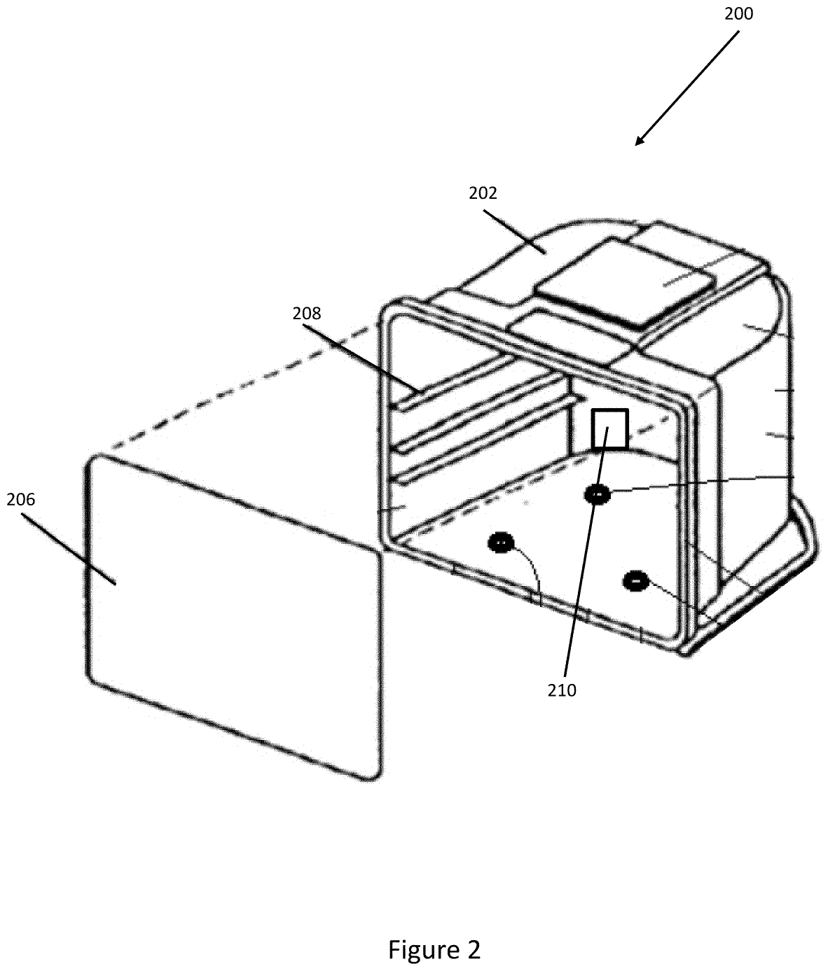

Adsorbent 100 is configured to be placed within a wafer container microenvironment. In an embodiment, adsorbent 100 is sized and shaped such that it can fit in one of the slots of the container used to accommodate wafers. In an embodiment, adsorbent 100 is shaped and sized similar or identical to the wafers to be accommodated within the wafer container, such as a 350 mm wafer or any other size and shape for wafers placed into a wafer container microenvironment. In an embodiment, adsorbent 100 is shaped and sized differently from the wafers to be accommodated within the wafer container while remaining capable of being inserted into and retained in one of the wafer slots of the wafer container. For example, a wafer container configured to accommodate round wafers could have an adsorbent 100 that is square in shape but sized to fit within the wafer slots of that wafer container. While the adsorbent 100 shown in FIG. 1 is sized and shaped to be placed within a wafer slot, it is understood that adsorbents of similar composition and/or construction can be made having sizes and shaped adapted for placement in an adsorbent holder provided within the wafer container, for example as described below and shown in FIG. 2.

Adsorbent body 102 is the main body of the adsorbent 100. Adsorbent body contains adsorbent media 104. In an embodiment, adsorbent body is a laminate containing a loading of the adsorbent media 104. Adsorbent body 102 can be shaped and sized such that the resulting adsorbent 100 can fit within an adsorbent holder within the wafer container, for example by cutting formed laminate including adsorbent media 104 to a predetermined shape.

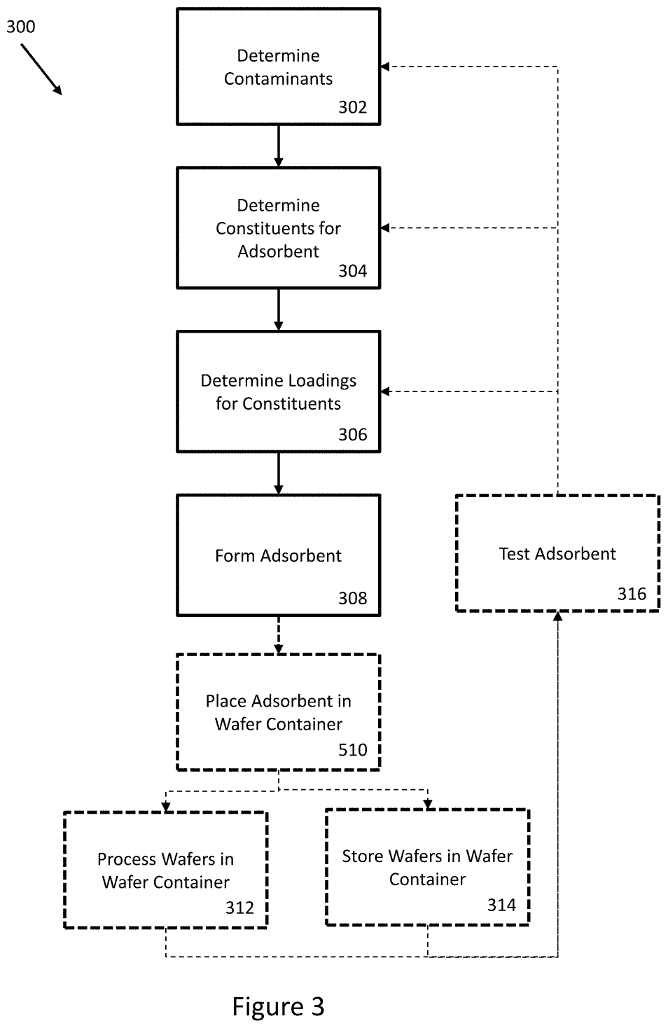

The adsorbent media 104 can include any one or more suitable adsorbents for removing one or more selected contaminants from a wafer container microenvironment. Non-limiting examples of contaminants include volatile organic compounds (VOCs), semi-condensable organic compounds, condensable organic compounds, acids, bases, ionic contaminants, and the like. The adsorbents can include, as non-limiting examples, carbon materials, molecular sieves, ion exchange resins, zeolites or any other suitable adsorbent or combinations thereof for removing contaminants from an environment. The loading of the adsorbent media 104 can be a loading, in terms of the media that is selected for inclusion and the amount of such selected media, that is selected to adsorb one or more specified target contaminants. The determination of target contaminants can be according to any suitable method, such as those described herein and shown in FIG. 3. The tailoring of the loading of adsorbent media 104 can improve the efficiency of the adsorbent media 104, since unnecessary or less effective constituents can be omitted from the adsorbent media. Adsorbent body 102 can further contain any suitable material for removal of moisture from the wafer container microenvironment, for example, one or more molecular sieves, desiccants, or the like.

The adsorbent main body 102 can be surrounded by a covering 106. The covering 106 can be any suitable porous material for packaging the adsorbent main body 102 while allowing passage of gas such that contaminants can be trapped by adsorbent media 104 for removal from the wafer container microenvironment. In an embodiment, the covering 106 can include a woven material and/or a non-woven material. In an embodiment, the covering 106 includes a polymer material. In an embodiment, the covering 106 can include a polyester nonwoven material. The covering 106 can include two or more portions joined to one another such that they surround the adsorbent main body. For example, the covering 106 can include two portions of material shaped similarly to the adsorbent main body 102 and sized slightly larger. The two portions of material can be placed on either side of the adsorbent main body and joined to one another at the perimeter 108 of the portions of material. The two or more portions of material can be joined by any suitable method of joining the portions of material, for example by way of a weld. In an embodiment, the weld is an ultrasonic weld.

FIG. 2 shows a wafer container configured to accommodate an adsorbent according to an embodiment. Wafer container 200 includes container body 202 including an open end 204 and door 206. The internal space defined by container body 202 includes wafer slots 208. Optionally, the wafer container 200 can include an adsorbent holder 210.

Wafer container 200 is a container used the processing, transport, and/or storage of wafers, such as semiconductor wafers. Wafer container 200 can be, for example, a front opening unified pod (FOUP). Container body 202 defines an internal space within wafer container 200, with open end 204 provided on one side of container body 202. Open end 204 can allow wafers to be placed with and/or removed from the internal space defined by container body 202. The door 206 can be used to close open end 204. When open end 204 is closed by door 206, a seal can be formed such that the internal space within wafer container 200 provides a microenvironment.

Inner surfaces of the container body 202 can include features defining wafer slots 208. The wafer slots 208 each can include one or more support structures for holding a wafer, such as flanges, tabs, beams, or any other suitable support structure. Each wafer slot 208 is configured to accommodate one wafer and position it within wafer container 200 in a manner suitable for processing, transport, and/or storage. In an embodiment, an adsorbent such as adsorbent 100 described above and shown in FIG. 1 can be placed into at least one of wafer slots 208 to adsorb targeted contaminants within the microenvironment within wafer container 200.

Optionally, the wafer container 200 can include adsorbent holder 210. Adsorbent holder 210 can be one or more structures separate from the wafer slots 208 that are configured to accommodate an adsorbent. The adsorbent holder 210 can include, for example, one or more clips, cages, pockets, or the like configured to retain the adsorbent within the microenvironment provided within wafer container 200. Adsorbent holders 210 can be integrated into or attached to at least one of wafer container body 202 and door 206. In an embodiment, adsorbent holder 210 can be integrated into any other suitable component integrated into or attached to wafer container body 202 or door 206, such as a license plate holder for the container, purge components, or the like. Each adsorbent holder 210 can be configured such that gas can pass through the adsorbent holder to interact with the adsorbent contained therein such that the adsorbent can remove contaminants from the contents of the microenvironment defined within wafer container 200.

FIG. 3 shows a flowchart of a method for reducing specific contaminants within a wafer container according to an embodiment. Method 300 includes determining one or more contaminants for removal from the wafer container microenvironment 302. Method 300 further includes selection one or more constituents for an adsorbent media based on the contaminants 304 and determining a loading for each of the constituents 306 based on the contaminants. The method 300 further includes preparing an adsorbent including the determined loading of the constituents 308. The method 300 can optionally include placing the adsorbent into a wafer container 310 and engaging in a wafer storage operation 312 or a wafer processing operation 314. In an embodiment, method 300 further includes testing of an adsorbent 316 following its placement into a wafer container at 310.

One or more contaminants for removal from a wafer container microenvironment can be determined at 302. The contaminants for removal can be contaminants that are particular to a wafer container microenvironment or a particular process or activity in that microenvironment. Selection of the contaminants can be based on the composition of the wafer container, staging conditions for the wafer container, processes the wafer container is used in, effects of or any other suitable criteria regarding the presence and/or effects of the contaminants. The contaminants for removal can be, for example, acids, bases, ionic contaminants, and/or organic compounds such as volatile organic compounds or condensable organic compounds. The contaminants for removal can include, as non-limiting examples, contaminants from an ambient environment such as staging or handling conditions, process chemicals, off-gassing products from the wafer container or contents thereof, moisture, or any other possible contaminant that can be present in the wafer container microenvironment.

In an embodiment, the determination of the one or more contaminants at 302 can include testing of an adsorbent that has been used in a representative wafer container microenvironment. For example, a sample adsorbent can be placed within a test wafer container and subsequently tested to determine the contaminants captured. In an embodiment, the method 300 can be iterated by testing an adsorbent prepared according to method 300 and placing the adsorbent in the microenvironment 310, and subsequent testing of that adsorbent 316. The contaminants for removal can be determined based on the results of such testing. The testing can be any suitable testing capable of identifying the presence or concentration of contaminants, such as, as non-limiting examples, thermogravimetric analysis, evolved gas analysis, gas chromatography mass spectroscopy, proton transfer reaction mass spectrometry, combinations thereof, and the like. In an embodiment, the contaminants for removal can be determined based on selection from the list, for example identifying the contaminants of greatest interest and determining those to be the contaminants for removal from the microenvironment. Contaminants of interest may be determined based on the effects of the contaminants on particular processes, any risks associated with the particular contaminants, their relative or absolute concentrations, or any other suitable criteria.

In an embodiment, the one or more contaminants can be determined at 302 based on knowledge of the particular conditions surrounding or at the wafer container microenvironment. In an embodiment, determining the one or more contaminants is based on ambient conditions during staging of a wafer container defining the wafer container microenvironment. In an embodiment, determining the one or more contaminants is based on one or more materials used in a process conducted within the wafer container microenvironment. In an embodiment, the one or more contaminants can be determined based on knowledge of potential off-gassing within the wafer container microenvironment, for example by being based on a material composition of the wafer container defining the wafer container microenvironment.

Method 300 further includes selection one or more constituents for an adsorbent media based on the contaminants 304. The constituents can be selected based on knowledge of the properties of the constituents with respect to the one or more determined contaminants. Non-limiting examples of constituents for the adsorbent media include carbon materials, molecular sieves, ion exchange resins, zeolites, and combinations thereof. Method 300 further includes determining a loading for each of the constituents 306. The loading includes an amount of each of the constituents, such as a mass of each constituent per area or volume of an adsorbent. The loading can be determined based on the relationships between the constituents and the one or more determined contaminants. In an embodiment, the loading can account for interactions among the constituents, for example any interactions affecting their adsorption effectiveness. In an embodiment, the loading is based on relative amounts of each of the contaminants to be absorbed. In an embodiment, the loading is based on relative importance of removing the contaminants, for example due to effects of the contaminants on a process carried out in the wafer container microenvironment. The determination of the constituents and the loading allows an adsorbent to be prepared that is tailored to the particular needs of a wafer container microenvironment or for particular uses of the wafer container and the microenvironment it defines.

Method 300 also includes preparing an adsorbent including the determined loading of the constituents 308. The adsorbent can be prepared by any suitable method for preparing an adsorbent. The adsorbent can be, for example, adsorbent 100 described above and shown in FIG. 1. In an embodiment, preparing the adsorbent at 308 can include providing a laminated body containing the loading determined at 306 for the constituents determined at 304. The preparation of the adsorbent at 308 can further include surrounding the adsorbent body with a covering, such as a porous covering such as a woven or non-woven material. The covering can be a polymer material such as a polymer. In an embodiment, the covering is a polyester non-woven material. The covering can be made to surround the adsorbent body by providing a plurality of covering segments that are joined, for example by a weld such as an ultrasonic weld. Excess material outside the weld can optionally be removed to result in the adsorbent.

The method 300 can optionally include placing the adsorbent into a wafer container 310. The placement of the adsorbent in the wafer container can be performed according to the size and shape of the adsorbent and the structure of the wafer container. In an embodiment, the adsorbent can be placed into a wafer slot of the wafer container. In an embodiment, the adsorbent can be placed in a holder located in an internal space defined by the wafer container. Once the adsorbent is placed within the wafer container, the wafer container can be closed to define a microenvironment. The adsorbent can remove contaminants from the microenvironment by adsorption of contaminants by the loading of constituents included in the adsorbent. Once the wafer container is closed, the wafer container can be used, for example by engaging in a wafer storage operation 312 or a wafer processing operation 314.

In an embodiment, method 300 further includes testing of an adsorbent 316 following its placement into a wafer container at 310. The testing can be, for example, destructive testing of the adsorbent media. The testing at 316 can, for example, be used to determine quantities of contaminants captured by the adsorbent when it is within the wafer container 310. Results of the testing at 316 can be used in iterations of the method 300 to refine the determination of contaminants at 302, the determination of constituents at 304, and/or the loading of the constituents in the adsorbent media at 306.

Table 1 shows results from a chromatogram of a sample taken from within an existing front opening unified pod (FOUP).

TABLE 1

| Concentration in: | ppbV | μg/m³ |
|---|---|---|
| Total Organics (both condensable and volatile) | 57 | 260 |
| Total Condensable Organics (HMW only) | 14 | 63 |

As shown in Table 1, the FOUP microenvironment includes significant presence of both condensable and volatile organics. Some of these organics can be undesirable depending on what is being stored or processed within the FOUP. In a non-limiting example, these chromatogram results can be used to identify one or more contaminants for removal from the FOUP microenvironment. For example, based on Table 1, adsorbent materials particular to removal of organics, particularly volatile organics, can be selected for inclusion in a loading for an adsorbent to be used in the FOUP.

Table 2 shows concentrations of total organics and total condensable organics obtained by way of a chromatogram of a sample taken from within a FOUP containing an adsorbent according to an embodiment. In the embodiment from which the chromatogram having results shown in Table 2, an adsorbent having constituents selected to remove toluene is placed within the FOUP microenvironment previously used in the generation of table 1.

TABLE 2

| Concentration in: | ppbV | μg/m³ |
|---|---|---|
| Total Organics (both condensable and volatile) | 5.6 | 25 |
| Total Condensable Organics (HMW only) | 0.1 | 0.6 |

As can be seen in Table 2, the results within the FOUP microenvironment including the adsorbent show significant reduction in content of volatile and condensable organics within the FOUP microenvironment. Compared to Table 1, addition of the adsorbent shows approximately a ten-fold reduction in the presence of organic compounds, including condensable organics, within the FOUP microenvironment. Accordingly, targeted adsorbents show an ability to drastically reduce the presence of the targeted contaminants within FOUP microenvironments. Similar targeting can be used for any suitable contaminant or combination of contaminants using loadings of adsorbents suitable for that contaminant or combination of contaminants.

Aspects:

Aspect 1. A method of reducing contamination within a wafer container microenvironment, comprising:

determining one or more contaminants for removal from the wafer container microenvironment;

selecting one or more constituents for an adsorbent media based on the one or more contaminants;

determining a loading for each of the one or more constituents based on the one or more contaminants;

preparing an adsorbent material including the determined loading of each of the one or more constituents, wherein the adsorbent material is configured to be placed within the wafer container microenvironment when wafers are present in the wafer container microenvironment.

Aspect 2. The method according to aspect 1, wherein the one or more constituents for the adsorbent media are selected from the group consisting of carbon materials, molecular sieves, ion exchange resins, and zeolites.

Aspect 3. The method according to any of aspects 1-2, wherein determining the one or more contaminants includes testing of a sample adsorbent that has been placed within a test wafer container microenvironment such that it has absorbed potential contaminants.

Aspect 4. The method according to any of aspects 1-3, wherein determining the loading for each of the one or more constituents includes testing of a sample adsorbent that has been placed within a test wafer container microenvironment such that it has absorbed potential contaminants.

Aspect 5. The method according to any of aspects 1-4, wherein determining the one or more contaminants is based on ambient conditions during staging of a wafer container defining the wafer container microenvironment.

Aspect 6. The method according to any of aspects 1-5, wherein determining the loading for each of the one or more constituents is based on ambient conditions during staging of a wafer container defining the wafer container microenvironment.

Aspect 7. The method according to any of aspects 1-6, wherein determining the one or more contaminants is based on a material composition of the wafer container defining the wafer container microenvironment.

Aspect 8. The method according to any of claims 1-7, wherein determining the loading for each of the one or more constituents is based on a material composition of the wafer container defining the wafer container microenvironment.

Aspect 9. The method according to any of aspects 1-8, wherein determining the one or more constituents is based on one or more materials used in a process conducted within the wafer container microenvironment.

Aspect 10. The method according to any of aspects 1-9, wherein determining the loading for each of the one or more constituents is based on one or more materials used in a process conducted within the wafer container microenvironment.

Aspect 11. The method according to any of aspects 1-10, wherein a wafer container defining the wafer container microenvironment is a front opening unified pod (FOUP).

Aspect 12. The method according to any of aspects 1-11, wherein the one or more contaminants selected from the group consisting of inorganic acids, bases, volatile organic compounds, and condensable organic compounds.

Aspect 13. The method according to any of aspects 1-12, wherein the adsorbent material is shaped such that it can fit in a wafer slot of the wafer container microenvironment.

Aspect 14. The method according to aspect 13, wherein the adsorbent material has the same shape and dimensions as wafers configured to be placed within the wafer container microenvironment.

Aspect 15. The method according to any of aspects 1-14, further comprising placing the adsorbent material within the wafer container microenvironment, and wherein the adsorbent material adsorbs the one or more contaminants when the contaminants are present within the microenvironment.

Aspect 16. The method according to aspect 15, wherein the adsorbent material adsorbs the one or more contaminants during a wafer processing operation.

Aspect 17. The method according to any of aspects 15-16, wherein the adsorbent material adsorbs the one or more contaminants during a wafer storage operation.

Aspect 18. The method according to any of aspects 1-17, wherein the adsorbent material is placed in an adsorbent holder located within the wafer container microenvironment.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A method of reducing contamination within a wafer container microenvironment, comprising:
determining one or more contaminants for removal from the wafer container microenvironment;
selecting one or more constituents for an adsorbent media based on the one or more contaminants;
determining a loading for each of the one or more constituents based on the one or more contaminants;
preparing an adsorbent material including the determined loading of each of the one or more constituents, wherein the adsorbent material is configured to be placed within the wafer container microenvironment when wafers are present in the wafer container microenvironment.

2. The method of claim 1, wherein the one or more constituents for the adsorbent media are selected from the group consisting of carbon materials, molecular sieves, ion exchange resins, and zeolites.

3. The method of claim 1, wherein determining the one or more contaminants includes testing of a sample adsorbent that has been placed within a test wafer container microenvironment such that it has absorbed potential contaminants.

4. The method of claim 1, wherein determining the loading for each of the one or more constituents includes testing of a sample adsorbent that has been placed within a test wafer container microenvironment such that it has absorbed potential contaminants.

5. The method of claim 1, wherein determining the one or more contaminants is based on ambient conditions during staging of a wafer container defining the wafer container microenvironment.

6. The method of claim 1, wherein determining the loading for each of the one or more constituents is based on ambient conditions during staging of a wafer container defining the wafer container microenvironment.

7. The method of claim 1, wherein determining the one or more contaminants is based on a material composition of the wafer container defining the wafer container microenvironment.

8. The method of claim 1, wherein determining the loading for each of the one or more constituents is based on a material composition of the wafer container defining the wafer container microenvironment.

9. The method of claim 1, wherein determining the one or more constituents is based on one or more materials used in a process conducted within the wafer container microenvironment.

10. The method of claim 1, wherein determining the loading for each of the one or more constituents is based on one or more materials used in a process conducted within the wafer container microenvironment.

11. The method of claim 1, wherein a wafer container defining the wafer container microenvironment is a front opening unified pod (FOUP).

12. The method of claim 1, wherein the one or more contaminants selected from the group consisting of inorganic acids, bases, volatile organic compounds, and condensable organic compounds.

13. The method of claim 1, wherein the adsorbent material is shaped such that it can fit in a wafer slot of the wafer container microenvironment.

14. The method of claim 13, wherein the adsorbent material has the same shape and dimensions as wafers configured to be placed within the wafer container microenvironment.

15. The method of claim 1, further comprising placing the adsorbent material within the wafer container microenvironment, and wherein the adsorbent material adsorbs the one or more contaminants when the contaminants are present within the microenvironment.

16. The method of claim 15, wherein the adsorbent material adsorbs the one or more contaminants during a wafer processing operation.

17. The method of claim 15, wherein the adsorbent material adsorbs the one or more contaminants during a wafer storage operation.

18. The method of claim 1, wherein the adsorbent material is placed in an adsorbent holder located within the wafer container microenvironment.
